(19) United States
(12) Patent Application Publication
(10) Pub. No.: US 2020/0135489 A1
(43) Pub. Date: Apr. 30, 2020

(54) METHOD FOR MAKING A SEMICONDUCTOR DEVICE INCLUDING A SUPERLATTICE HAVING NITROGEN DIFFUSED THEREIN

(71) Applicant: ATOMERA INCORPORATED, Los Gatos, CA (US)

(72) Inventors: KEITH DORAN WEEKS, CHANDLER, AZ (US); NYLES WYNN CODY, TEMPE, AZ (US); MAREK HYTHA, BROOKLINE, MA (US); ROBERT J. MEARS, WELLESLEY, MA (US); ROBERT JOHN STEPHENSON, DUXFORD (GB); LOUIS NICHOLAS HUTTER, III, DALLAS, TX (US)

(21) Appl. No.: 16/176,005

(22) Filed: Oct. 31, 2018

(51) Int. Cl. H01L 21/322; H01L 29/15; H01L 29/16; H01L 21/02

(52) U.S. Cl. CPC H01L 21/3221; H01L 29/152; H01L 29/16; H01L 21/0262; H01L 21/0245; H01L 21/02488; H01L 21/02507

(57) ABSTRACT

A method for making a semiconductor device may include forming a superlattice layer and an adjacent semiconductor layer. The superlattice layer may include a plurality of stacked groups of layers, with each group of layers comprising a plurality of stacked base semiconductor monolayers defining a base semiconductor portion, and at least one non-semiconductor monolayer constrained within a crystal lattice of adjacent base semiconductor portions. The method may further include diffusing nitrogen into the superlattice layer.

### TECHNICAL FIELD

The present disclosure generally relates to semiconductor devices and, more particularly, to semiconductor device fabrication techniques utilizing enhanced semiconductor materials.

### BACKGROUND

Structures and techniques have been proposed to enhance the performance of semiconductor devices, such as by enhancing the mobility of the charge carriers. For example, U.S. Patent Application No. 2003/0057416 to Currie et al. discloses strained material layers of silicon, silicon-germanium, and relaxed silicon and also including impurity-free zones that would otherwise cause performance degradation. The resulting biaxial strain in the upper silicon layer alters the carrier mobilities enabling higher speed and/or lower power devices. Published U.S. Patent Application No. 2003/0034529 to Fitzgerald et al. discloses a CMOS inverter also based upon similar strained silicon technology.

U.S. Pat. No. 6,472,685 B2 to Takagi discloses a semiconductor device including a silicon and carbon layer sandwiched between silicon layers so that the conduction band and valence band of the second silicon layer receive a tensile strain. Electrons having a smaller effective mass, and which have been induced by an electric field applied to the gate electrode, are confined in the second silicon layer, thus, an re-channel MOSFET is asserted to have a higher mobility.

U.S. Pat. No. 4,937,204 to Ishibashi et al. discloses a superlattice in which a plurality of layers, less than eight monolayers, and containing a fractional or binary or a binary compound semiconductor layer, are alternately and epitaxially grown. The direction of main current flow is perpendicular to the layers of the superlattice.

U.S. Pat. No. 5,357,119 to Wang et al. discloses a Si—Ge short period superlattice with higher mobility achieved by reducing alloy scattering in the superlattice. Along these lines, U.S. Pat. No. 5,683,934 to Candelaria discloses an enhanced mobility MOSFET including a channel layer comprising an alloy of silicon and a second material substitutionally present in the silicon lattice at a percentage that places the channel layer under tensile stress.

U.S. Pat. No. 5,216,262 to Tsu discloses a quantum well structure comprising two barrier regions and a thin epitaxially grown semiconductor layer sandwiched between the barriers. Each barrier region consists of alternate layers of SiO2/Si with a thickness generally in a range of two to six monolayers. A much thicker section of silicon is sandwiched between the barriers.

An article entitled “Phenomena in silicon nanostructure devices” also to Tsu and published online Sep. 6, 2000 by Applied Physics and Materials Science & Processing, pp. 391-402 discloses a semiconductor-atomic superlattice (SAS) of silicon and oxygen. The Si/O superlattice is disclosed as useful in a silicon quantum and light-emitting devices. In particular, a green electroluminescence diode structure was constructed and tested. Current flow in the diode structure is vertical, that is, perpendicular to the layers of the SAS. The disclosed SAS may include semiconductor layers separated by adsorbed species such as oxygen atoms, and CO molecules. The silicon growth beyond the adsorbed monolayer of oxygen is described as epitaxial with a fairly low defect density. One SAS structure included a 1.1 nm thick silicon portion that is about eight atomic layers of silicon, and another structure had twice this thickness of silicon. An article to Luo et al. entitled “Chemical Design of Direct-Gap Light-Emitting Silicon” published in Physical Review Letters, Vol. 89, No. 7 (Aug. 12, 2002) further discusses the light emitting SAS structures of Tsu.

Published International Application WO 02/103,767 A1 to Wang, Tsu and Lofgren, discloses a barrier building block of thin silicon and oxygen, carbon, nitrogen, phosphorous, antimony, arsenic or hydrogen to thereby reduce current flowing vertically through the lattice more than four orders of magnitude. The insulating layer/barrier layer allows for low defect epitaxial silicon to be deposited next to the insulating layer.

Published Great Britain Patent Application 2,347,520 to Mears et al. discloses that principles of Aperiodic Photonic Band-Gap (APBG) structures may be adapted for electronic bandgap engineering. In particular, the application discloses that material parameters, for example, the location of band minima, effective mass, etc., can be tailored to yield new aperiodic materials with desirable band-structure characteristics. Other parameters, such as electrical conductivity, thermal conductivity and dielectric permittivity or magnetic permeability are disclosed as also possible to be designed into the material.

Furthermore, U.S. Pat. No. 6,376,337 to Wang et al. discloses a method for producing an insulating or barrier layer for semiconductor devices which includes depositing a layer of silicon and at least one additional element on the silicon substrate whereby the deposited layer is substantially free of defects such that epitaxial silicon substantially free of defects can be deposited on the deposited layer. Alternatively, a monolayer of one or more elements, preferably comprising oxygen, is absorbed on a silicon substrate. A plurality of insulating layers sandwiched between epitaxial silicon forms a barrier composite.

### SUMMARY

A method for making a semiconductor device may include forming a superlattice layer and an adjacent semiconductor layer. The superlattice layer may include a plurality of stacked groups of layers, with each group of layers comprising a plurality of stacked base semiconductor monolayers defining a base semiconductor portion, and at least one non-semiconductor monolayer constrained within a crystal lattice of adjacent base semiconductor portions. The method may further include diffusing nitrogen into the superlattice layer.

In accordance with one embodiment, the adjacent semiconductor layer may comprise nitrogen, and diffusing nitrogen into the superlattice layer may include diffusing nitrogen from the adjacent semiconductor layer into the superlattice layer. In one example, the method may include implanting nitrogen into the adjacent semiconductor layer. In another embodiment, the method may include diffusing nitrogen into the adjacent semiconductor layer.

By way of example, the adjacent semiconductor layer may comprise a semiconductor substrate beneath the superlattice layer. In accordance with another example, the adjacent semiconductor layer may comprise a semiconductor cap above the superlattice layer. By way of example, diffusing nitrogen from the adjacent semiconductor layer into the superlattice layer may comprise annealing the superlattice layer and adjacent semiconductor layer. In one example implementation, the adjacent semiconductor layer may comprise a semiconductor cap layer on the superlattice layer, and diffusing nitrogen into the superlattice layer may comprise annealing the semiconductor cap layer and superlattice layer in a nitrogen atmosphere.

By way of example, the semiconductor cap layer may have a thickness in a range of 400 Å to 500 Å. Also by way of example, a nitrogen concentration within the superlattice layer may be in a range of 1×10¹⁸ atoms/cm³ to 1×10²¹ atoms/cm³, for example, although higher concentrations are also possible in some embodiments. In addition, each base semiconductor portion may comprise silicon, and the at least one non-semiconductor layer may comprise oxygen, for example. In some embodiments, nitrogen and/or oxygen may be removed from the adjacent semiconductor layer prior for forming the superlattice layer.

### BRIEF DESCRIPTION OF THE DRAWINGS

FIG. 1 is a greatly enlarged schematic cross-sectional view of a superlattice for use in a semiconductor device in accordance with an example embodiment.

FIG. 2 is a perspective schematic atomic diagram of a portion of the superlattice shown in FIG. 1.

FIG. 3 is a greatly enlarged schematic cross-sectional view of another embodiment of a superlattice in accordance with an example embodiment.

FIG. 4A is a graph of the calculated band structure from the gamma point (G) for both bulk silicon as in the prior art, and for the 4/1 Si/O superlattice as shown in FIGS. 1-2.

FIG. 4B is a graph of the calculated band structure from the Z point for both bulk silicon as in the prior art, and for the 4/1 Si/O superlattice as shown in FIGS. 1-2.

FIG. 4C is a graph of the calculated band structure from both the gamma and Z points for both bulk silicon as in the prior art, and for the 5/1/3/1 Si/O superlattice as shown in FIG. 3.

FIGS. 5-8 are flow diagrams illustrating methods for diffusing nitrogen in superlattice structures in accordance with example embodiments.

FIG. 9 is a flow diagram of a CMOS integration process including an MST superlattice module with nitrogen diffusion such as those shown in FIGS. 5-8.

FIG. 10 is a graph of oxygen and nitrogen concentration vs. depth for an example superlattice structure fabricated without performing nitrogen diffusion.

FIGS. 11-12 are graphs of oxygen and nitrogen concentration vs. depth for example superlattice structures fabricated using two different nitrogen diffusion recipes in accordance with example embodiments.

### DETAILED DESCRIPTION

Example embodiments will now be described more fully hereinafter with reference to the accompanying drawings, in which the example embodiments are shown. The embodiments may, however, be implemented in many different forms and should not be construed as limited to the specific examples set forth herein. Rather, these embodiments are provided so that this disclosure will be thorough and complete. Like numbers refer to like elements throughout, and prime notation is used to indicate similar elements in different embodiments.

Generally speaking, the present disclosure relates to semiconductor wafer processing and device fabrication techniques which utilize an enhanced semiconductor superlattice as a gettering layer to prevent metal contamination in the device layer of a chip. The enhanced semiconductor superlattice is also referred to as an “MST” layer or “MST technology” in this disclosure, which may be deposited in a blanket approach (“MST1”), or selectively at desired locations (“MST2”). Further background on the use of MST technology may be found in U.S. Pat. No. 9,275,996 to Mears et al., which is hereby incorporated herein in its entirety by reference.

More particularly, the MST technology relates to advanced semiconductor materials such as the superlattice 25 described further below. Applicant theorizes, without wishing to be bound thereto, that certain superlattices as described herein reduce the effective mass of charge carriers and that this thereby leads to higher charge carrier mobility. Effective mass is described with various definitions in the literature. As a measure of the improvement in effective mass Applicant's use a “conductivity reciprocal effective mass tensor”, Mₑ⁻¹ and Mₕ⁻¹ for electrons and holes respectively, defined as:

$${M}_{e , ij}^{- 1} ( {E}_{F} , T ) = \frac{{\sum }_{E > {E}_{F}} {\int }_{B . Z .} {( {∇}_{k} E ( k , n ) )}_{i} {( {∇}_{k} E ( k , n ) )}_{j} \frac{\partial f ( E ( k , n ) , {E}_{F} , T )}{\partial E} {d}^{3} k}{{\sum }_{E > {E}_{F}} {\int }_{B . Z .} f ( E ( k , n ) , {E}_{F} , T ) {d}^{3} k}$$

for electrons and:

$${M}_{h , ij}^{- 1} ( {E}_{F} , T ) = \frac{- {\sum }_{E < {E}_{F}} {\int }_{B . Z .} {( {∇}_{k} E ( k , n ) )}_{i} {( {∇}_{k} E ( k , n ) )}_{j} \frac{\partial f ( E ( k , n ) , {E}_{F} , T )}{\partial E} {d}^{3} k}{{\sum }_{E < {E}_{F}} {\int }_{B . Z .} ( 1 - f ( E ( k , n ) , {E}_{F} , T ) ) {d}^{3} k}$$

for holes, where f is the Fermi-Dirac distribution, E_{F} is the Fermi energy, T is the temperature, E(k,n) is the energy of an electron in the state corresponding to wave vector k and the n^{th} energy band, the indices i and j refer to Cartesian coordinates x, y and z, the integrals are taken over the Brillouin zone (B.Z.), and the summations are taken over bands with energies above and below the Fermi energy for electrons and holes respectively.

Applicant's definition of the conductivity reciprocal effective mass tensor is such that a tensorial component of the conductivity of the material is greater for greater values of the corresponding component of the conductivity reciprocal effective mass tensor. Again Applicant theorizes without wishing to be bound thereto that the superlattices described herein set the values of the conductivity reciprocal effective mass tensor so as to enhance the conductive properties of the material, such as typically for a preferred direction of charge carrier transport. The inverse of the appropriate tensor element is referred to as the conductivity effective mass. In other words, to characterize semiconductor material structures, the conductivity effective mass for electrons/holes as described above and calculated in the direction of intended carrier transport is used to distinguish improved materials.

Applicant has identified improved materials or structures for use in semiconductor devices. More specifically, Applicant has identified materials or structures having energy band structures for which the appropriate conductivity effective masses for electrons and/or holes are substantially less than the corresponding values for silicon. In addition to the enhanced mobility characteristics of these structures, they may also be formed or used in such a manner that they provide piezoelectric, pyroelectric, and/or ferroelectric properties that are advantageous for use in a variety of different types of devices, as will be discussed further below.

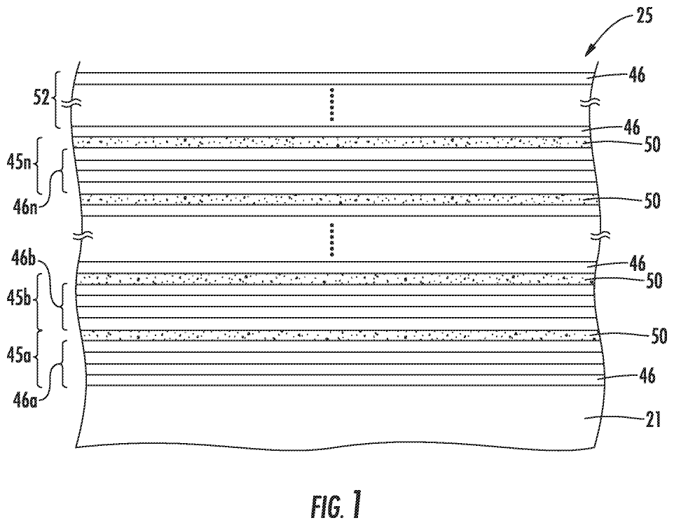

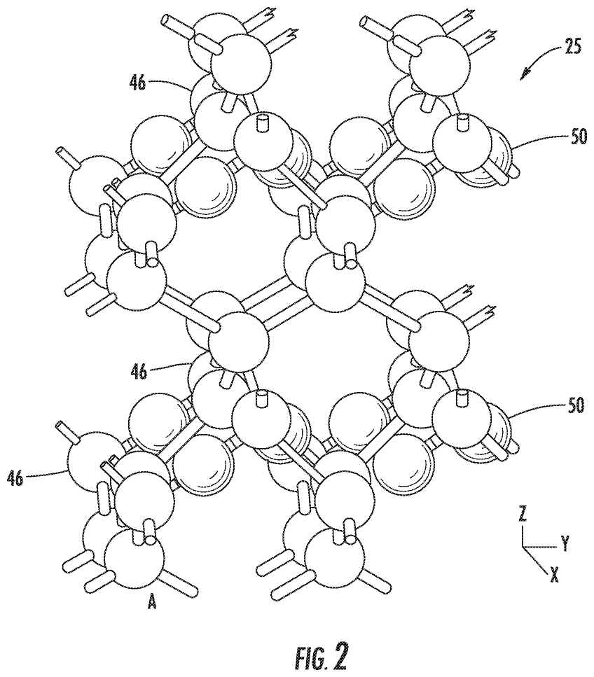

Referring now to FIGS. 1 and 2, the materials or structures are in the form of a superlattice 25 whose structure is controlled at the atomic or molecular level and may be formed using known techniques of atomic or molecular layer deposition. The superlattice 25 includes a plurality of layer groups 45a-45n arranged in stacked relation, as perhaps best understood with specific reference to the schematic cross-sectional view of FIG. 1.

Each group of layers 45a-45n of the superlattice 25 illustratively includes a plurality of stacked base semiconductor monolayers 46 defining a respective base semiconductor portion 46a-46n and an energy band-modifying layer 50 thereon. The energy band-modifying layers 50 are indicated by stippling in FIG. 1 for clarity of illustration.

The energy band-modifying layer 50 illustratively includes one non-semiconductor monolayer constrained within a crystal lattice of adjacent base semiconductor portions. By “constrained within a crystal lattice of adjacent base semiconductor portions” it is meant that at least some semiconductor atoms from opposing base semiconductor portions 46a-46n are chemically bound together through the non-semiconductor monolayer 50 therebetween, as seen in FIG. 2. Generally speaking, this configuration is made possible by controlling the amount of non-semiconductor material that is deposited on semiconductor portions 46a-46n through atomic layer deposition techniques so that not all (i.e., less than full or 100% coverage) of the available semiconductor bonding sites are populated with bonds to non-semiconductor atoms, as will be discussed further below. Thus, as further monolayers 46 of semiconductor material are deposited on or over a non-semiconductor monolayer 50, the newly deposited semiconductor atoms will populate the remaining vacant bonding sites of the semiconductor atoms below the non-semiconductor monolayer.

In other embodiments, more than one such non-semiconductor monolayer may be possible. It should be noted that reference herein to a non-semiconductor or semiconductor monolayer means that the material used for the monolayer would be a non-semiconductor or semiconductor if formed in bulk. That is, a single monolayer of a material, such as silicon, may not necessarily exhibit the same properties that it would if formed in bulk or in a relatively thick layer, as will be appreciated by those skilled in the art.

Applicant theorizes without wishing to be bound thereto that energy band-modifying layers 50 and adjacent base semiconductor portions 46a-46n cause the superlattice 25 to have a lower appropriate conductivity effective mass for the charge carriers in the parallel layer direction than would otherwise be present. Considered another way, this parallel direction is orthogonal to the stacking direction. The band modifying layers 50 may also cause the superlattice 25 to have a common energy band structure, while also advantageously functioning as an insulator between layers or regions vertically above and below the superlattice.

Moreover, this superlattice structure may also advantageously act as a barrier to dopant and/or material diffusion between layers vertically above and below the superlattice 25. These properties may thus advantageously allow the superlattice 25 to provide an interface for high-K dielectrics which not only reduces diffusion of the high-K material into the channel region, but which may also advantageously reduce unwanted scattering effects and improve device mobility, as will be appreciated by those skilled in the art.

It is also theorized that semiconductor devices including the superlattice 25 may enjoy a higher charge carrier mobility based upon the lower conductivity effective mass than would otherwise be present. In some embodiments, and as a result of the band engineering achieved by the present invention, the superlattice 25 may further have a substantially direct energy bandgap that may be particularly advantageous for opto-electronic devices, for example.

The superlattice 25 also illustratively includes a cap layer 52 on an upper layer group 45n. The cap layer 52 may comprise a plurality of base semiconductor monolayers 46. The cap layer 52 may range from 2 monolayers to 25 Å or more (e.g., 100 Å or greater) of the base semiconductor, and, more preferably between 10 to 50 monolayers.

Each base semiconductor portion 46a-46n may comprise a base semiconductor selected from the group consisting of Group IV semiconductors, Group III-V semiconductors, and Group II-VI semiconductors. Of course, the term Group IV semiconductors also includes Group IV-IV semiconductors, as will be appreciated by those skilled in the art. More particularly, the base semiconductor may comprise at least one of silicon and germanium, for example.

Each energy band-modifying layer 50 may comprise a non-semiconductor selected from the group consisting of oxygen, nitrogen, fluorine, carbon and carbon-oxygen, for example. The non-semiconductor is also desirably thermally stable through deposition of a next layer to thereby facilitate manufacturing. In other embodiments, the non-semiconductor may be another inorganic or organic element or compound that is compatible with the given semiconductor processing as will be appreciated by those skilled in the art. More particularly, the base semiconductor may comprise at least one of silicon and germanium, for example.

It should be noted that the term monolayer is meant to include a single atomic layer and also a single molecular layer. It is also noted that the energy band-modifying layer 50 provided by a single monolayer is also meant to include a monolayer wherein not all of the possible sites are occupied (i.e., there is less than full or 100% coverage). For example, with particular reference to the atomic diagram of FIG. 2, a 4/1 repeating structure is illustrated for silicon as the base semiconductor material, and oxygen as the energy band-modifying material. Only half of the possible sites for oxygen are occupied in the illustrated example.

In other embodiments and/or with different materials this one-half occupation would not necessarily be the case as will be appreciated by those skilled in the art. Indeed it can be seen even in this schematic diagram, that individual atoms of oxygen in a given monolayer are not precisely aligned along a flat plane as will also be appreciated by those of skill in the art of atomic deposition. By way of example, a preferred occupation range is from about one-eighth to one-half of the possible oxygen sites being full, although other numbers may be used in certain embodiments.

Silicon and oxygen are currently widely used in conventional semiconductor processing, and, hence, manufacturers will be readily able to use these materials as described herein. Atomic or monolayer deposition is also now widely used. Accordingly, semiconductor devices incorporating the superlattice 25 in accordance with the invention may be readily adopted and implemented, as will be appreciated by those skilled in the art.

It is theorized without Applicant wishing to be bound thereto that for a superlattice, such as the Si/O superlattice, for example, that the number of silicon monolayers should desirably be seven or less so that the energy band of the superlattice is common or relatively uniform throughout to achieve the desired advantages. The 4/1 repeating structure shown in FIGS. 1 and 2, for Si/O has been modeled to indicate an enhanced mobility for electrons and holes in the X direction. For example, the calculated conductivity effective mass for electrons (isotropic for bulk silicon) is 0.26 and for the 4/1 SiO superlattice in the X direction it is 0.12 resulting in a ratio of 0.46. Similarly, the calculation for holes yields values of 0.36 for bulk silicon and 0.16 for the 4/1 Si/O superlattice resulting in a ratio of 0.44.

While such a directionally preferential feature may be desired in certain semiconductor devices, other devices may benefit from a more uniform increase in mobility in any direction parallel to the groups of layers. It may also be beneficial to have an increased mobility for both electrons and holes, or just one of these types of charge carriers as will be appreciated by those skilled in the art.

The lower conductivity effective mass for the 4/1 Si/O embodiment of the superlattice 25 may be less than two-thirds the conductivity effective mass than would otherwise occur, and this applies for both electrons and holes. Of course, the superlattice 25 may further comprise at least one type of conductivity dopant therein, as will also be appreciated by those skilled in the art.

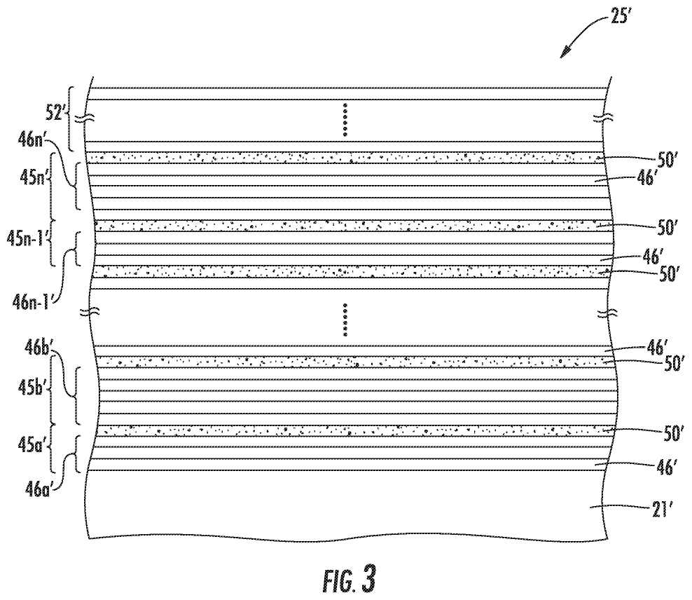

Indeed, referring now additionally to FIG. 3, another embodiment of a superlattice 25′ in accordance with the invention having different properties is now described. In this embodiment, a repeating pattern of 3/1/5/1 is illustrated. More particularly, the lowest base semiconductor portion 46a′ has three monolayers, and the second lowest base semiconductor portion 46b′ has five monolayers. This pattern repeats throughout the superlattice 25′. The energy band-modifying layers 50′ may each include a single monolayer. For such a superlattice 25′ including Si/O, the enhancement of charge carrier mobility is independent of orientation in the plane of the layers. Those other elements of FIG. 3 not specifically mentioned are similar to those discussed above with reference to FIG. 1 and need no further discussion herein.

In some device embodiments, all of the base semiconductor portions of a superlattice may be a same number of monolayers thick. In other embodiments, at least some of the base semiconductor portions may be a different number of monolayers thick. In still other embodiments, all of the base semiconductor portions may be a different number of monolayers thick.

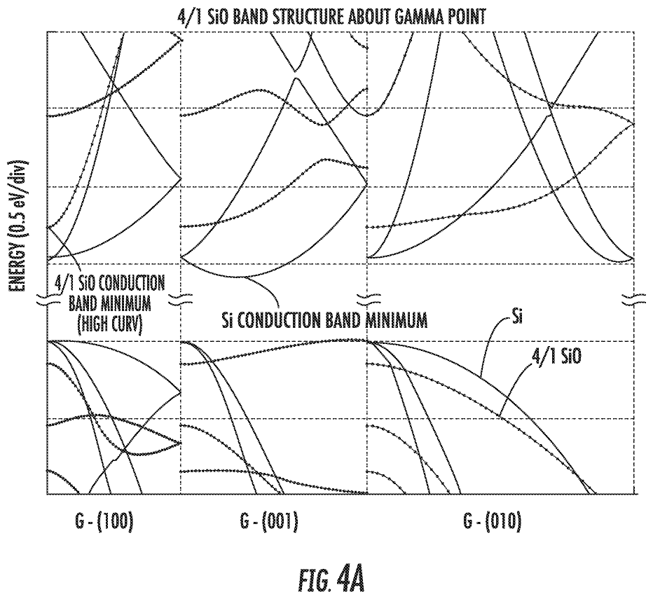

In FIGS. 4A-4C, band structures calculated using Density Functional Theory (DFT) are presented. It is well known in the art that DFT underestimates the absolute value of the bandgap. Hence all bands above the gap may be shifted by an appropriate “scissors correction.” However the shape of the band is known to be much more reliable. The vertical energy axes should be interpreted in this light.

FIG. 4A shows the calculated band structure from the gamma point (G) for both bulk silicon (represented by continuous lines) and for the 4/1 Si/O superlattice 25 shown in FIG. 1 (represented by dotted lines). The directions refer to the unit cell of the 4/1 Si/O structure and not to the conventional unit cell of Si, although the (001) direction in the figure does correspond to the (001) direction of the conventional unit cell of Si, and, hence, shows the expected location of the Si conduction band minimum. The (100) and (010) directions in the figure correspond to the (110) and (−110) directions of the conventional Si unit cell. Those skilled in the art will appreciate that the bands of Si on the figure are folded to represent them on the appropriate reciprocal lattice directions for the 4/1 Si/O structure.

It can be seen that the conduction band minimum for the 4/1 Si/O structure is located at the gamma point in contrast to bulk silicon (Si), whereas the valence band minimum occurs at the edge of the Brillouin zone in the (001) direction which we refer to as the Z point. One may also note the greater curvature of the conduction band minimum for the 4/1 Si/O structure compared to the curvature of the conduction band minimum for Si owing to the band splitting due to the perturbation introduced by the additional oxygen layer.

FIG. 4B shows the calculated band structure from the Z point for both bulk silicon (continuous lines) and for the 4/1 Si/O superlattice 25 (dotted lines). This figure illustrates the enhanced curvature of the valence band in the (100) direction.

FIG. 4C shows the calculated band structure from both the gamma and Z point for both bulk silicon (continuous lines) and for the 5/1/3/1 Si/O structure of the superlattice 25′ of FIG. 3 (dotted lines). Due to the symmetry of the 5/1/3/1 Si/O structure, the calculated band structures in the (100) and (010) directions are equivalent. Thus the conductivity effective mass and mobility are expected to be isotropic in the plane parallel to the layers, i.e. perpendicular to the (001) stacking direction. Note that in the 5/1/3/1 Si/O example the conduction band minimum and the valence band maximum are both at or close to the Z point.

Although increased curvature is an indication of reduced effective mass, the appropriate comparison and discrimination may be made via the conductivity reciprocal effective mass tensor calculation. This leads Applicant to further theorize that the 5/1/3/1 superlattice 25′ should be substantially direct bandgap. As will be understood by those skilled in the art, the appropriate matrix element for optical transition is another indicator of the distinction between direct and indirect bandgap behavior.

Having described example MST structures and methods for their fabrications, various example approaches will now be described for incorporating nitrogen in the above-described MST superlattice structures. Generally speaking, the approaches described herein involve forming a superlattice layer and diffusing nitrogen into the superlattice layer from an adjacent semiconductor layer above or below the superlattice. Another approach is also provided for implanting nitrogen ions in the superlattice layer (or adjacent semiconductor layer), and diffusing the nitrogen ions within the superlattice layer through annealing.

By way of background, nitrogen incorporation may enhance the properties of MST films used for applications such as dopant blocking and mobility enhancement in semiconductor devices. The nitrogen improves dopant blocking, stabilizes oxygen, and retards oxygen from being lost into the surrounding semiconductor lattice as a result of subsequent processes and thermal anneals. At high enough nitrogen concentrations, the combination of MST film oxygen monolayers with nitrogen may be used to provide enhanced insulating layers below the single crystal silicon in a semiconductor-on-insulator (SOI) configuration. SOI is used in semiconductor devices to better isolate the active devices from one another and the bulk semiconductor substrate, as will be appreciated by those skilled in the art.

Nitrogen has also been used for impurity engineering of Czochralski silicon growth. In this application, Si₃N₄ is dissolved into the silicon melt that the silicon ingots are to be pulled from, but nitrogen is incorporated into the silicon lattice at much lower concentrations than may be used in accordance with the nitrogen infusion approaches described herein. More particularly, the present approaches may be used to introduce nitrogen in single crystal silicon to pin dislocation inside the silicon, as opposed to a method of dissolving silicon nitride into the melt from which silicon ingots will be pulled, and wafers sawed from the ingot.

Nitrogen lock-in also helps prevent dislocation defects from gliding to the surface where sensitive electronic devices will be built. Targeted nitrogen also may act as a getter of other elements. Nitrogen gettering may be used to pin highly mobile undesirable metal contaminants in a targeted subsurface region away from the area where the electronic devices are to be built.

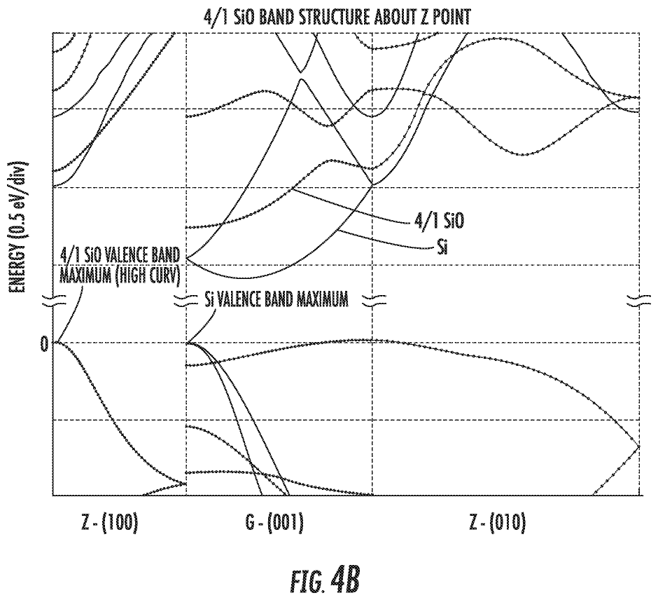

Referring now to the flow diagram 100 of FIG. 5, beginning at Block 101, an MST layer 25 is formed on a substrate or wafer 21 as described above, either by blanket deposition across the wafer (MST1) or selective deposition in desired locations on the wafer (MST2), at Block 102. Moreover, a semiconductor cap layer 52 may optionally be formed on the MST layer as well, at Block 103. The structure is then subjected to an anneal in a nitrogen atmosphere, at Block 104, which diffuses nitrogen into the MST layer 25 after it has already been formed. When a cap layer 52 is included, the nitrogen will diffuse into the MST layer 25 by way of the cap layer 52. By way of example, the semiconductor cap layer may have a thickness in a range of 400 Å to 500 Å, although different thicknesses may be used in different embodiments. The method of FIG. 5 illustratively concludes at Block 105.

By diffusing nitrogen into the MST film monolayers after epitaxial deposition, this allows for a greater final dosage of nitrogen to boost dopant blocking and mobility enhancement. MST superlattice inserted oxygen monolayers are deposited as described above, resulting in device enhancements including increases in carrier mobility and dopant blocking, for example. After deposition, the inserted oxygen monolayers may undergo other thermal processes such as dopant activation anneals, and source drain dopant implant activation. If the thermal budget is high enough, these oxygen monolayers can be disturbed from their desired “as deposited” arrangement. In some cases, thermal cycling at elevated temperatures may cause a reduction in the quantum mechanical properties of the MST film, and/or reduce the efficiency of impurity blocking. The addition of nitrogen advantageously helps to prevent or minimize the movement of oxygen during thermal annealing.

One particular advantage of the approach shown in FIG. 5 for nitrogen incorporation is that it allows for MST film formation using standard deposition approaches or recipes without modification, followed by the proper surface preparation and annealing in nitrogen. By way of contrast, typical approaches for generating oxynitride films are to grow or deposit an oxynitride layer using precursors flown at the proper ratios to give the desired target nitrogen and oxygen ratios in the layer. However, by adding nitrogen to a band engineered superlattice stack, the oxygen is stabilized/held in place when introduced to high temperature thermal cycles that the wafer will undergo during implant dopant activation anneals, for example.

Nitrogen incorporation may also boost the blocking and quantum mechanical properties of MST films above those with oxygen alone. Since in this embodiment the nitrogen is moved to the targeted MST regions after MST film stack deposition, a much higher total impurity dose may be achieved in the final MST superlattice without generating defects in the final product. That is, there is a finite amount of oxygen and nitrogen that may be introduced during the epitaxial growth without epitaxial order being lost, but nitrogen diffusion after the fact may advantageously allow for a greater amount of nitrogen to be incorporated in the MST film than if performed during MST film deposition.

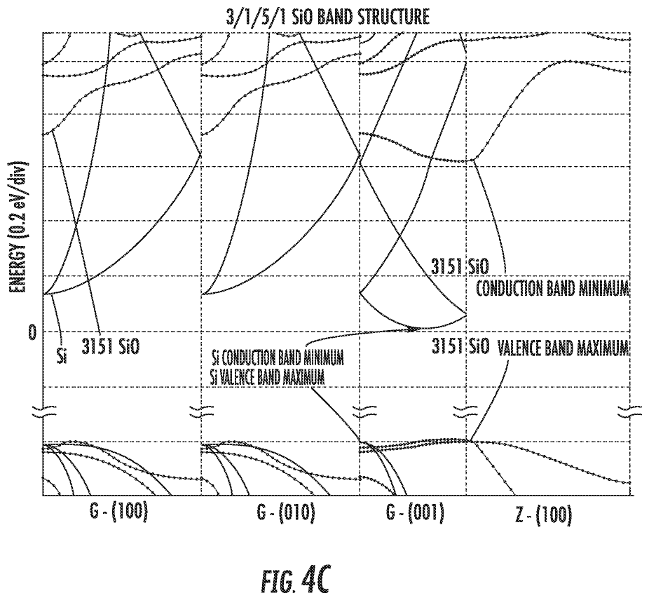

Nevertheless, referring now to the flow diagram 110 of FIG. 6, in some embodiments nitrogen may be incorporated within the MST film during its growth with additional process requalification with the addition of a nitrogen precursor. Generally speaking, process complexity increases with the addition of a new growth species (here nitrogen). For example, one cannot simply add a nitrogen containing source to the existing CVD process without expecting there to be a change in the desired oxygen content. The change in the gas chemistry may either reduce or increase the oxygen content in the resulting film. Depending on the deposition conditions, the nitrogen may compete for sites in the silicon lattice, resulting in reduced oxygen within the final structure.

Beginning at Block 111, as the semiconductor (e.g., silicon) and oxygen monolayers 46, 50 of the MST superlattice 25 are grown, at Block 112, nitrogen may be introduced in the process (Block 113). In this regard, certain process/precursor sections may be used to enhance the final oxygen content. Low temperature precursors capable of nitrogen incorporation at temperatures below 600° C., such as Hydrazine N₂H₄, may be used, but generally require extra safety precautions to work with. Another approach is to use a remote plasma generator to break down diatomic N₂ into atomic nitrogen to generate a source of nitrogen suitable for low temperature processing. A semiconductor cap 52 may optionally be formed, at Block 114, followed by subsequent processing steps. The method of FIG. 6 illustratively concludes at Block 115.

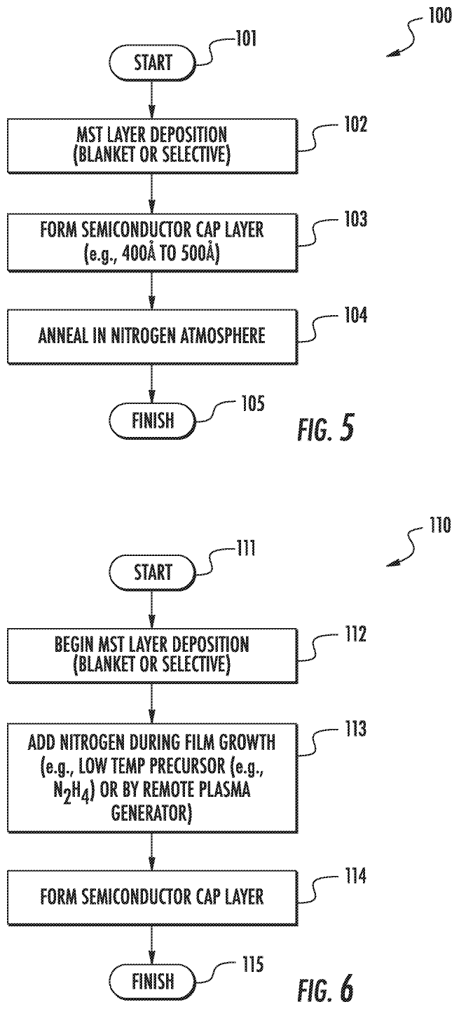

Turning now to the flow diagram 120 of FIG. 7, beginning at Block 121, still another example approach for diffusing nitrogen into an MST superlattice 25 involves annealing the wafer or substrate 21 in nitrogen before epitaxial MST growth, at Block 122. Precautions may be taken to help ensure that the silicon surface of the substrate 21 is oxygen free before the anneal, as will be appreciated by those skilled in the art. More particularly, the nitrogen will be stored in the substrate 21 lattice. The wafers 21 may be removed and the surface treated to remove any residual nitrogen that would prevent epitaxial MST growth, at Block 123. The full MST superlattice stack may then be deposited on the wafers 21 (which may be a selective or blanket deposition), at Block 124, followed by an anneal at an appropriate temperature and time to move the nitrogen into the MST superlattice stack, at Block 125. By way of example, this second annealing environment may be N₂, H₂, or another carrier gas since the nitrogen would have been moved into the substrate 21 during the first anneal process (Block 122). The method illustrated in FIG. 7 illustratively concludes at Block 126.

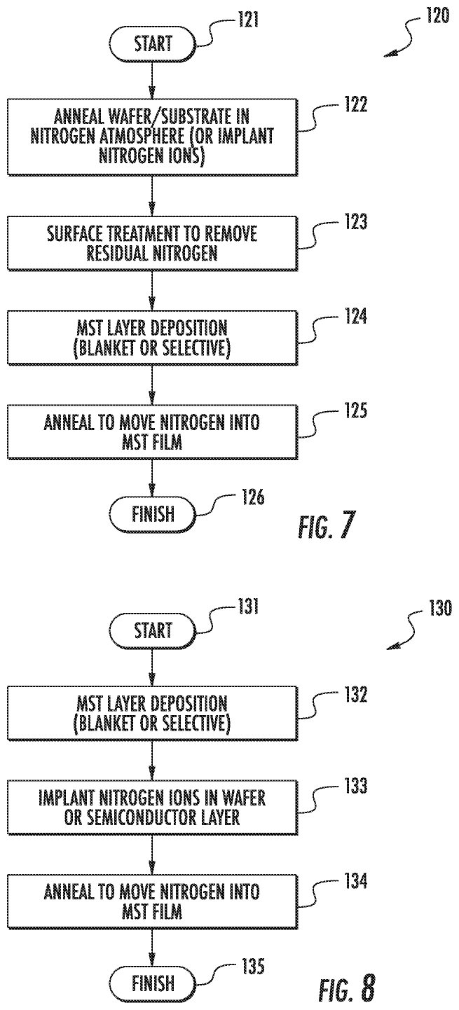

In accordance with another example embodiment described now with reference to the flow diagram 130 of FIG. 8, nitrogen is diffused into the MST superlattice 25 through nitrogen ion implantation. Beginning at Block 131, after formation of the MST epitaxial stack on a wafer or substrate 21, at Block 132, implantation with nitrogen may be performed at an energy appropriate to place the nitrogen in the lattice at the desired depth, as will be appreciated by those skilled in the art (Block 133). Once the nitrogen is in the wafer 21 (or an overlying cap/active semiconductor layer in some embodiments), it may be annealed for a length of time necessary to allow the nitrogen to diffuse into the MST film 25 as discussed above (Block 134). Alternatively, the nitrogen may be implanted into the wafer 21 before MST film 25 growth. Then the wafer 21 may be annealed after MST film growth to move the nitrogen into the MST monolayers, similar to the embodiment described above with reference to FIG. 7. The method illustrated in FIG. 8 illustratively concludes at Block 135.

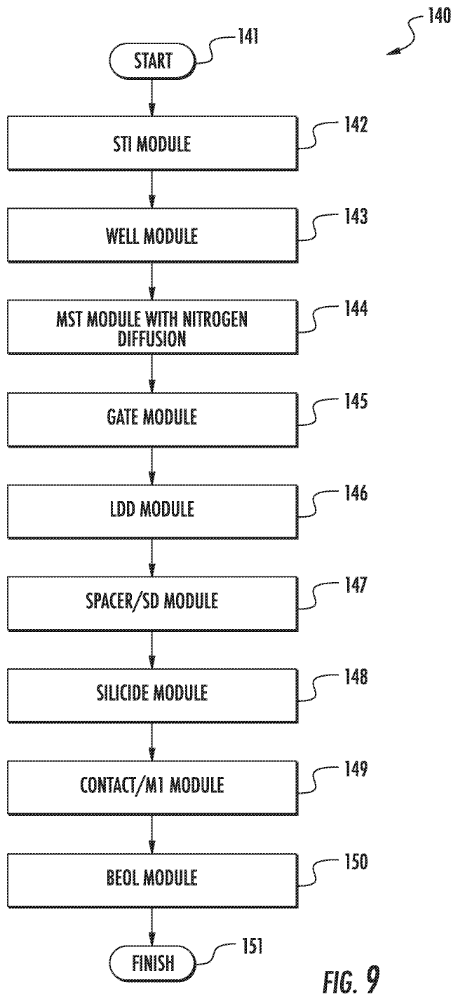

Turning to the flow diagram 140 of FIG. 9, an example CMOS process flow in which a nitrogen-infused MST superlattice module may be incorporated is now described. The process begins (Block 141) with a shallow trench isolation (STI) module 142, followed by a well module 143 (e.g., for a threshold voltage (V_{T}) implant). An MST superlattice module with nitrogen diffusion may then be performed, at Block 144, such as described above with reference to FIGS. 5-8. The process flow may further include a gate module 145, a lightly doped drain (LDD) module 146, a spacer and source/drain (SD) module 147, a silicide module 148, a contact/M1 module 149, and a back end of line (BEOL) module 150. As noted above, the superlattice epitaxy may be done in either a blanket form across an entire wafer (MST1) or selectively at different locations on the water (MST2) in different embodiments. It should be noted that certain steps and modules may be performed in different orders in different embodiments, depending upon the type of semiconductor device being created. Moreover, CMOS devices are but one example semiconductor device in which nitrogen-infused MST superlattices may be used, and it will be appreciated that this superlattice configuration may be used in numerous other types of semiconductor devices as well (e.g., diodes, vertical devices such as FINFETs, etc.).

It will accordingly be appreciated that the above-described configurations advantageously provide several different approaches for incorporating nitrogen into MST films using an anneal which could be before, after, or during MST deposition. In those cases where annealing is performed after depositing the desired MST stack (with or without silicon capping), the annealing may be performed either within the same process recipe or after unloading the wafers and processing the structures in the same or a different machine at a later time. There are advantages to either approach depending on the application and the resources available. For example, one may only have access to a single chamber epitaxial reactor, so the deposition and N₂ anneal would in that case be completed in the same reactor. In this case the temperature and other process flows and precursors may be ramped to the desired set points, and the nitrogen anneal conducted in the same reactor process recipe. Another alternative would be to unload the wafer with the MST superlattice from the reactor and reload the wafer at a future time to be nitrogen annealed. Still another processing approach would be to use a batch reaction, such as processing the MST superlattice on the wafers in a furnace, and then annealing them in a nitrogen environment (either in-situ or ex-situ).

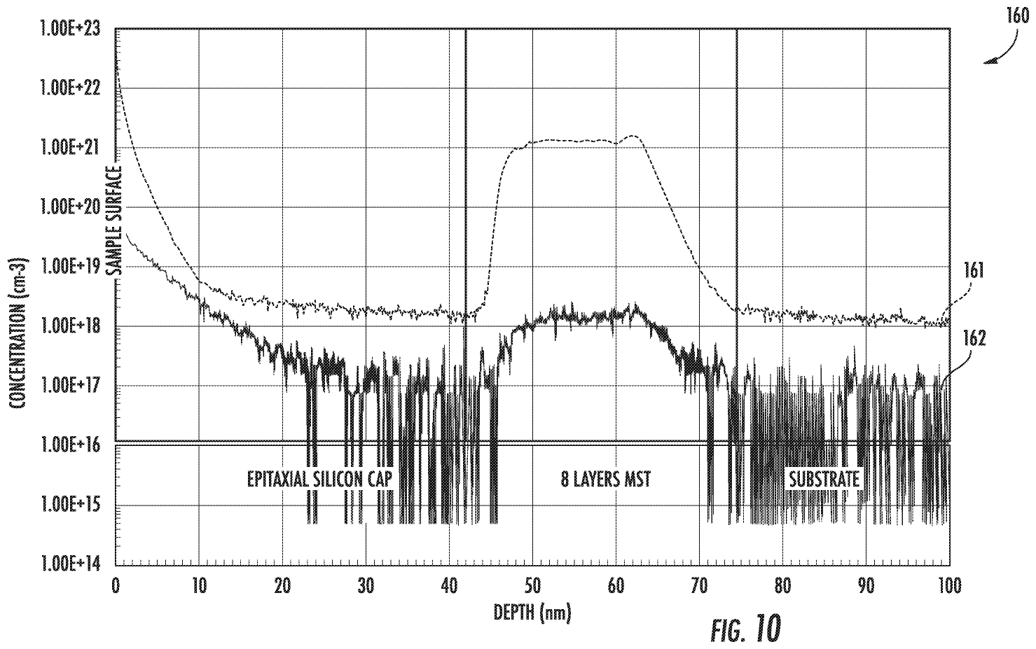

Referring now to FIGS. 10-12, three respective graphs 160, 170, 180 of secondary-ion mass spectrometry (SIMS) data are provided corresponding to three different MST film process flows. In these examples, an 8/1 repeating Si/O superlattice structure was fabricated for each of the tests with approximately a 450 Å silicon cap. The first example shown in the graph 160 corresponds to an MST film fabricated with no additional nitrogen diffusion added. The MST oxygen monolayers were generated with an N₂O gas source, resulting in a relatively small amount of nitrogen in the MST layer (the nitrogen dose is represented by plot line 162). The total oxygen dose (represented by plot line 161) in the MST superlattice is 2.26E15 atoms/cm². However, in other embodiments a different oxygen source may be used that does not include nitrogen and oxygen in the chemistry, in which case even less (or no) nitrogen will be present in the MST superlattice. In either case, there is no impact on the ability to perform nitrogen diffusion post MST film formation.

In the second example shown in the graph 170, the same MST film structure was fabricated but with a ten-minute atmospheric pressure post-epi MST/cap anneal in the presence of N₂. The MST film plus silicon cap was generated with an identical chemical vapor deposition process to that used in the example of FIG. 10, but now an oxygen dose (plot line 171) of 2.33E15 atoms/cm² in the MST film and a nitrogen dose (plot line 172) of 2.76E14 atoms/cm². Within the accuracy of the SIMS, the oxygen dose in the MST layer was maintained or slightly increased as a result of the nitrogen diffusion operations. If this anneal had been done in H₂ gas rather than N₂, a significant amount (e.g., 10 to 30 percent of the oxygen dose) of oxygen would have been lost as a result of the 900° C. anneal, ATM pressure (roughly 730 torr where the structures were fabricated) and ten-minute annealing period.

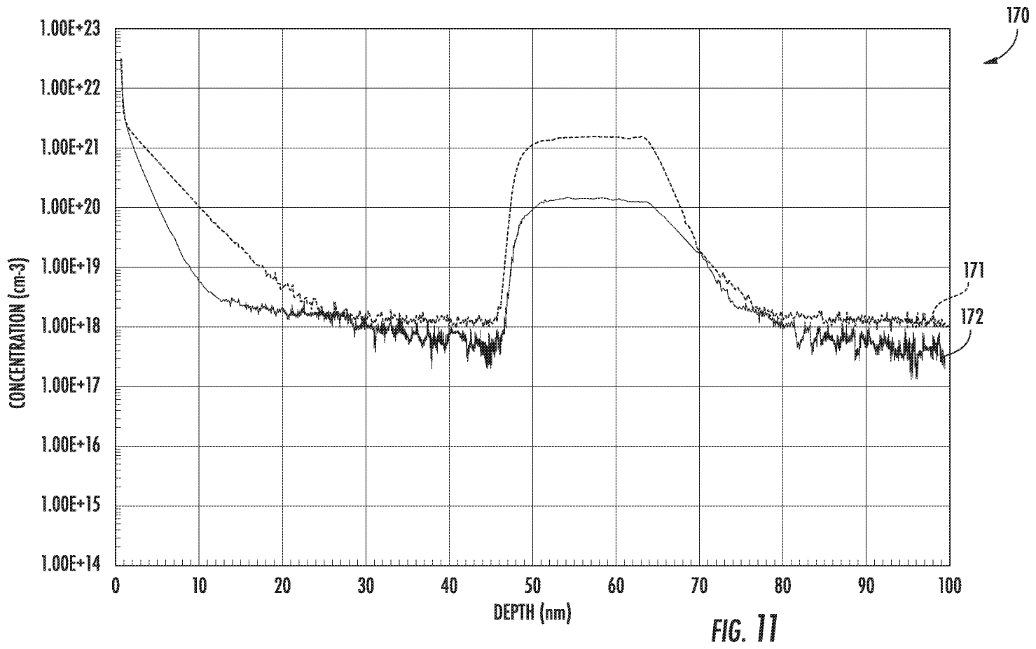

In the final example shown in the graph 180, a similar process was used for forming the MST film plus silicon cap, but here a 900° C., twenty-minute atmospheric pressure N₂ post-MST film growth anneal was used. It may be seen that the oxygen dose (plot line 181) is 2.41E15 atoms/cm², but the nitrogen dose (plot line 182) is now 3.79E14 atoms/cm². Within the accuracy of the SIMS, the oxygen dose is again maintained or slightly increased. The in-film nitrogen content has increased by nearly 50% as compared to the ten-minute annealing time in the example of FIG. 11.

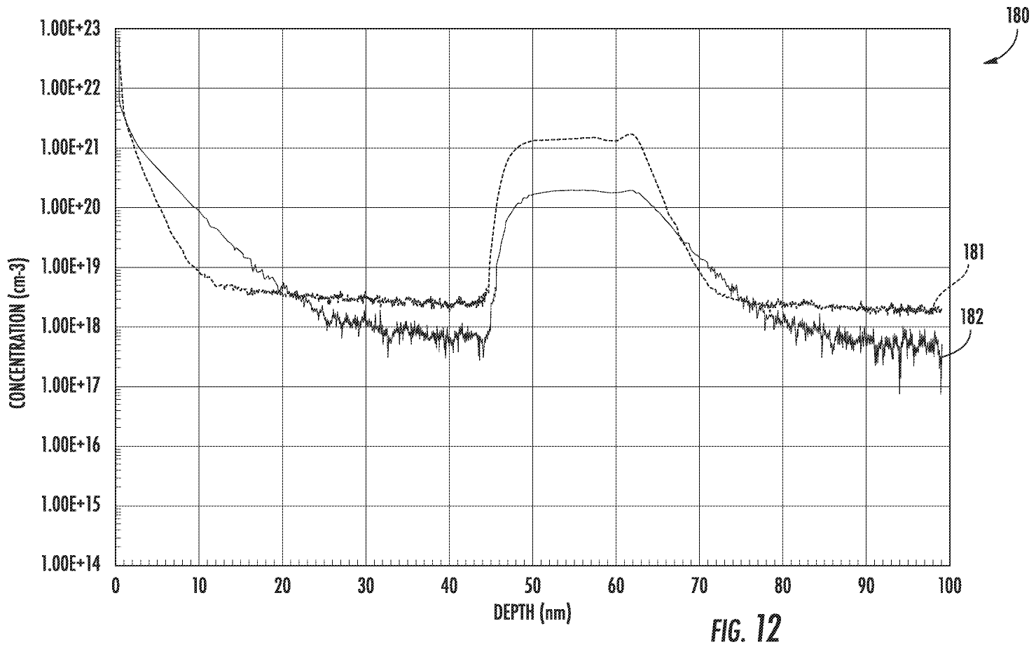

It will be appreciated from the increased surface nitrogen signal of the SIMS profiles that the surface nitrogen has increase significantly in the examples of FIGS. 11 and 12 compared to the example of FIG. 10. N₂ gas has likely decomposed on the wafer and bonded with the silicon surface atoms. Once the N₂ has reacted, surface nitrogen diffuse to the subsurface oxygen in the MST monolayers. The nitrogen diffuses through the silicon cap at a concentration at or below the detection limit of SIMS, which is approximately 1E18 atoms/cm³ for these SIMS. The nitrogen piles up in the MST monolayers, tightly replicating the original oxygen profile. The amount of nitrogen remaining on the surface may be controlled by completing the anneal in H₂ gas, for example. Nitrogen still on the surface from the N₂ annealing steps may continue to diffuse to the oxygen in the MST film until the source of nitrogen is depleted, or the nitrogen within the MST layers is saturated.

Surface preparation is important for the annealing in nitrogen environment portion. In order for the nitrogen to be incorporated into the MST epitaxial growth, the wafer surface should be oxygen free and preferably remain hydrogen terminated, as opposed to the surface being oxidized. If, for example, the MST layers are unloaded from the rector to the atmosphere, a thin native silicon oxide layer will form on its surface. This thin native oxide helps prevent the N₂ gas from reacting at the wafer's surface, which in turn helps prevent any nitrogen from being incorporated into the MST monolayers during the anneal step. The surface of the sample should accordingly be kept relatively free of oxygen to provide desired results. By “free of oxygen” it is meant that less than a native oxide is present on the surface. More particularly, it may be desirable that less than a monolayer of silicon dioxide remains, and even more particularly that less than a tenth of a monolayer of oxygen should remain on the sample surface before starting the N₂ anneal.

One may achieve a silicon surface with minimal oxygen in several ways. For example, the MST film with silicon cap may remain within the deposition reactor (with no oxygen source present) and then nitrogen annealed. This will help ensure that the wafer sees minimal oxygen (i.e., anything in the atmosphere that contains oxygen, e.g., O₂, CO, CO₂, H₂O, etc.) contamination before the anneal starts. Another approach is to wet clean MST wafers in HF before putting the wafers back into a reactor in which the nitrogen anneal will be performed. A properly-executed HF wet etch will reduce oxygen on the wafer surface to a level less than one complete monolayer, and leave the wafer surface hydrogen-terminated to protect the surface from oxidation during the transport to the reactor load lock.

In another example approach, the MST film plus silicon cap may be grown in a hydrogen environment and then, before unloading, the wafer cooled down in the hydrogen environment to a temperature below 400° C., and more particularly below 250° C. Unloading the wafer at these low temperatures will help ensure that the wafer's surface bonds will become and remain hydrogen terminated upon exiting the reactor. This hydrogen termination will protect the surface of the wafer from oxidizing with the environment outside of the reactor. When the wafer is reloaded into a reactor, one can help ensure that the surface remains hydrogen terminated by reloading at a temperature below 400° C. and ramping the reactor temperature up to the nitrogen annealing temperature.

Still another approach to help ensure that the wafer is free of oxygen is to use ASM's Previum™ or AMAT's Siconi™ preclean modules. These types of pre-clean modules are attached to the same platforms as the epi chambers. Wafers may be processed/treated in the preclean module and then passed from the preclean module to the process module where the anneal will take place such that oxygen on the surface of the wafer is minimized. One skilled in the art of epitaxial growth will know how to prevent and or remove oxide from the wafer surface in preparation for the implementation of the nitrogen diffusion. The list above is not intended to be a complete list of the many ways to preserve/prepare a silicon or other semiconductor surface that is free of unwanted oxygen, and others may be used in different embodiments.

While the above-described test structures corresponding to FIGS. 11 and 12 were fabricated with diatomic nitrogen (N₂), other nitrogen sources such as atomic nitrogen, NH₃, N₂H₆, or others may also be used. In the case of N₂, the gas decomposes on the hydrogen terminated silicon substrate surface, after which some of the nitrogen atoms diffuse several tens of angstroms through the silicon lattice to the inserted oxygen monolayers. The nitrogen and oxygen are pined in this region. The concentration of the nitrogen on either side of the abrupt region of incorporation is relatively low (at or below the detection limit of the SIMS). A wide range of concentrations of nitrogen may be obtained depending on the temperature, time, nitrogen source flow rate, and the original oxygen concentration. Pressure effects the process to a lesser degree than time and temperature. Based on the SIMS from the examples of FIGS. 11 and 12, the nitrogen in the leading edge of the nitrogen incorporated region without performing nitrogen diffusions is less than 1E18 atoms/cm³ (at or below the SIMS detection limit for these samples data sets), and rises to a peak concentration at or above 1E20 atoms/cm³ in the MST film stack.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims.

That which is claimed is:

1. A method for making a semiconductor device comprising:
forming a superlattice layer and an adjacent semiconductor layer, the superlattice layer comprising a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions; and
diffusing nitrogen into the superlattice layer.

2. The method of claim 1 wherein the adjacent semiconductor layer comprises nitrogen; and wherein diffusing nitrogen into the superlattice layer comprises diffusing nitrogen from the adjacent semiconductor layer into the superlattice layer.

3. The method of claim 2 further comprising implanting nitrogen into the adjacent semiconductor layer.

4. The method of claim 2 further comprising diffusing nitrogen into the adjacent semiconductor layer.

5. The method of claim 2 wherein the adjacent semiconductor layer comprises a semiconductor substrate beneath the superlattice layer.

6. The method of claim 2 wherein the adjacent semiconductor layer comprises a semiconductor cap above the superlattice layer.

7. The method of claim 2 wherein diffusing nitrogen from the adjacent semiconductor layer into the superlattice layer comprises annealing the superlattice layer and adjacent semiconductor layer.

8. The method of claim 1 wherein the adjacent semiconductor layer comprises a semiconductor cap layer on the superlattice layer; and wherein diffusing nitrogen into the superlattice layer comprises annealing the semiconductor cap layer and superlattice layer in a nitrogen atmosphere.

9. The method of claim 8 wherein the semiconductor cap layer has a thickness in a range of 400 Å to 500 Å.

10. The method of claim 1 wherein a nitrogen concentration within the superlattice layer is in a range of 1×10¹⁸ atoms/cm³ to 1×10²¹ atoms/cm³.

11. The method of claim 1 further comprising removing oxygen from the adjacent semiconductor layer prior to forming the superlattice layer.

12. The method of claim 1 further comprising removing oxygen from the adjacent semiconductor layer prior to forming the superlattice layer.

13. The method of claim 1 wherein each base semiconductor portion comprises silicon.

14. The method of claim 1 wherein the at least one non-semiconductor layer comprises oxygen.

15. A method for making a semiconductor device comprising:
forming a superlattice layer on a semiconductor substrate comprising nitrogen, the superlattice layer comprising a plurality of stacked groups of layers, each group of layers comprising a plurality of stacked base silicon monolayers defining a base silicon portion, and at least one oxygen monolayer constrained within a crystal lattice of adjacent base silicon portions; and
diffusing nitrogen from the adjacent semiconductor substrate into the superlattice layer.

16. The method of claim 15 further comprising implanting nitrogen into the semiconductor substrate.

17. The method of claim 15 further comprising diffusing nitrogen into the semiconductor substrate.

18. The method of claim 15 wherein a nitrogen concentration within the superlattice layer is in a range of 1×10¹⁸ atoms/cm³ to 1×10²¹ atoms/cm³.

19. A method for making a semiconductor device comprising:
forming a superlattice layer on a semiconductor substrate and forming a semiconductor cap above the superlattice layer, the superlattice layer comprising a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions; and
diffusing nitrogen into the superlattice layer from the semiconductor cap layer.

20. The method of claim 19 wherein diffusing nitrogen into the superlattice layer comprises annealing the semiconductor cap layer and superlattice layer in a nitrogen atmosphere.

21. The method of claim 19 wherein the semiconductor cap layer has a thickness in a range of 400 Å to 500 Å.

22. The method of claim 19 wherein a nitrogen concentration within the superlattice layer is in a range of 1×10¹⁸ atoms/cm³ to 1×10²¹ atoms/cm³.

23. The method of claim 19 wherein each base semiconductor portion comprises silicon.

24. The method of claim 19 wherein the at least one non-semiconductor layer comprises oxygen.
